(19) United States
(12) Patent Application Publication
(10) Pub. No.: US 2026/0221384 A1
(43) Pub. Date: Jul. 30, 2026

(54) Processing Method and Charged Particle Beam Device

(71) Applicant: Hitachi High-Tech Corporation, Minato-ku, Tokyo (JP)

(72) Inventors: Kensuke SHIINA, Tokyo (JP); Tatsuya ASAHATA, Tokyo (JP)

(21) Appl. No.: 19/143,009

(22) PCT Filed: Jan. 31, 2023
(86) PCT No.: PCT/JP2023/002984

§ 371 Date: Jun. 25, 2025

(51) Int. Cl. H01J 37/305; H01J 37/28

(52) U.S. Cl. CPC H01J 37/3053; H01J 37/28; H01J 2237/2807; H01J 2237/31745; H01J 2237/31749

(57) ABSTRACT

A charged particle beam apparatus processes a sample in which a plurality of layers including a specific layer are stacked. The charged particle beam apparatus includes a focused ion beam column, a charged particle beam column, and a processor. The charged particle beam apparatus executes processing of exposing the specific layer. The processor determines whether there is a defect based on reference data regarding the specific layer and the observation image after it is determined that the specific layer is exposed. When it is determined that there is a defect, the processor specifies a type of the defect based on an observation image of the sample by using a trained model. The charged particle beam apparatus executes different processing according to whether there is the defect and/or according to the specified type of the defect.

### TECHNICAL FIELD

The present invention relates to a processing method and a charged particle beam apparatus.

### BACKGROUND ART

As one of methods for analyzing an internal structure of a sample such as a semiconductor device or performing three-dimensional observation, for example, a cross-section processing and observation method is known in which a plurality of cross-sectional images of a sample are acquired by scanning the sample with an electron beam (EB) with a scanning electron microscope (SEM) while repeating cross-section formation processing (etching processing) using a focused ion beam (FIB), and then a three-dimensional image of the sample is configured by superimposing the plurality of cross-sectional images (for example, PTL 1).

This cross-section processing and observation method is a method of continuous cross-section processing and observation (also referred to as Cut & See) using a composite charged particle beam apparatus, and has an advantage that the cross-sectional image of the sample can be viewed and the three-dimensional observation of an inner portion of the sample can be performed from various directions, which is not provided in other methods.

As a specific example, etching processing is performed by irradiating a sample with an FIB to expose a cross section of the sample. Subsequently, the exposed cross section is subjected to SEM observation to obtain a cross-sectional image. Subsequently, etching processing is performed again to expose a next cross section, and then a second cross-sectional image is obtained by SEM observation. In this way, the etching processing and the SEM observation are repeated along any direction of the sample to acquire a plurality of cross-sectional images. Finally, a three-dimensional image through an inner portion of the sample is configured by superimposing the plurality of acquired cross-sectional images.

### CITATION LIST

### Patent Literature

PTL 1: JP 2015-50126A

### SUMMARY OF INVENTION

### Technical Problem

In an FIB system that processes a sample, it is required to expose a desired cross section of the sample, observe the cross section, select and execute processing content such as subsequent analysis processing, detailed observation, and finishing processing based on the observation result, and execute processing according to a state of the sample. However, in order to select appropriate processing from a plurality of options based on the observation result, a specialized determination is required. In addition, since parameters necessary for performing the processing are different for each sample, complicated work is required for setting.

The invention has been made in view of such circumstances, and an object of the invention is to execute desired processing while eliminating the need for specialized determination and complicated work performed by a human by automatically performing desired processing based on a state of a cross section of a sample.

### Solution to Problem

An example of a processing method according to the invention is a processing method for a sample in which a plurality of layers are stacked, the processing method including:
irradiating the sample with a focused ion beam to expose at least one of the layers;
irradiating the exposed layer with a charged particle beam to generate an observation image of the layer;
when it is determined that there is a defect, specifying a type or a shape of the defect based on an observation image of the sample by using a trained model; and
executing different processing according to the specified type or shape of the defect.

An example of a charged particle beam apparatus according to the invention is a charged particle beam apparatus for processing a sample in which a plurality of layers are stacked, the charged particle beam apparatus including:
a focused ion beam column;
a charged particle beam column; and
a processor, in which
the focused ion beam column irradiates the sample with a focused ion beam to expose the layer,
the charged particle beam column irradiates the exposed layer with a charged particle beam,
the processor
   generates an observation image of the layer, and
   when it is determined that there is a defect, specifies a type or a shape of the defect based on an observation image of the sample by using a trained model, and
the charged particle beam apparatus executes different processing according to the specified type or shape of the defect.

### Advantageous Effects of Invention

With the processing method and the charged particle beam apparatus according to the invention, it is possible to execute desired processing while eliminating the need for specialized determination and complicated work performed by a human by automatically performing desired processing based on a state of a cross section of a sample.

### BRIEF DESCRIPTION OF DRAWINGS

FIG. 1 is a diagram illustrating a configuration example of a charged particle beam apparatus according to Embodiment 1.

FIG. 2 is a diagram illustrating a configuration example of a control unit according to Embodiment 1.

FIG. 3 is a diagram illustrating an example of a method of generating a trained model according to Embodiment 1.

FIG. 4 is a flowchart of a processing method according to Embodiment 1.

### DESCRIPTION OF EMBODIMENTS

Hereinafter, an embodiment of the invention will be described with reference to the accompanying drawings.

### Embodiment 1

Hereinafter, a charged particle beam apparatus according to the embodiment will be described with reference to the drawings.

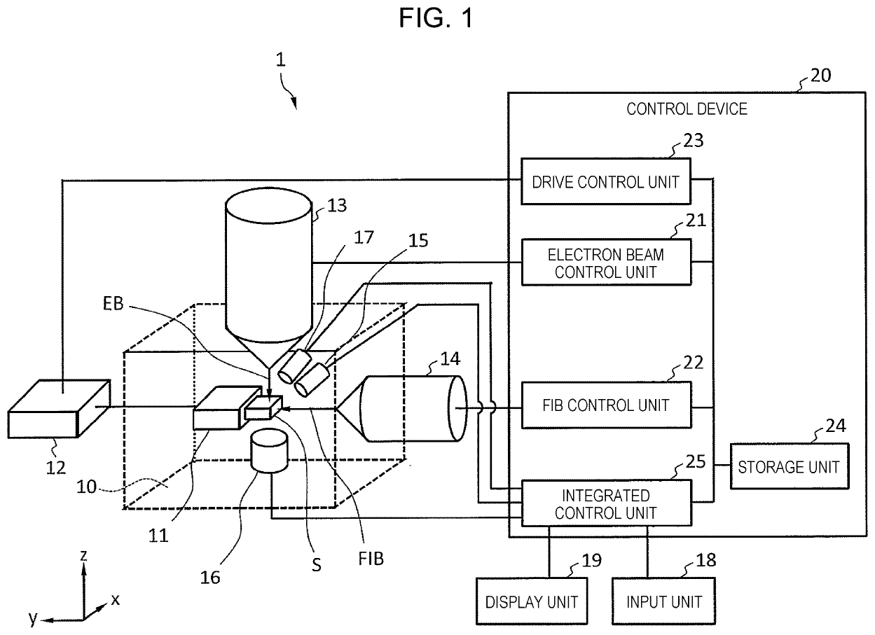

FIG. 1 is a diagram illustrating an example of a schematic configuration of a charged particle beam apparatus 1 according to Embodiment 1. The charged particle beam apparatus 1 executes a method of processing a sample S by irradiating the sample S, in which a plurality of layers are stacked, with a focused ion beam, that is, processes the sample S.

For example, when a specific layer (specific layer) of the sample S, in which a plurality of layers are stacked, is observed by a transmission electron microscope or the like, it is necessary to process a cross section of the sample S to expose the specific layer. At this time, the charged particle beam apparatus 1 performs processing to expose the specific layer, and determines whether the specific layer is exposed based on an SEM image of the cross section of the sample. In addition, it is determined whether a defect is in the exposed specific layer. When there is a defect, a type or shape of the defect is determined, and predetermined processing is executed according to the type or shape of the defect. One of features of the embodiment is to determine a state of the specific layer of the sample S and automatically select and execute predetermined next processing.

The sample S is a sample in which a plurality of layers including the specific layer are stacked in a predetermined stacking direction. The specific layer is, for example, a layer made of a material (for example, a semiconductor) to be observed. In the sample S, one or more layers not to be observed may be stacked in the stacking direction together with a plurality of specific layers. The layer not to be observed is, for example, a layer made of a material that is not to be observed (for example, a metal conductor used as a transmission path of power or a signal). A specific example of the sample S is a 3D-NAND flash memory.

The stacking direction may be any direction. For example, the stacking direction of the sample S accommodated in a sample chamber 10 may be an up-down direction or a left-right direction.

Hereinafter, the configuration of the charged particle beam apparatus 1 according to the embodiment will be described more specifically.

As illustrated in FIG. 1, the charged particle beam apparatus 1 includes the sample chamber 10, a sample stage 11, a drive mechanism 12, an electron beam column 13 (charged particle beam column), a focused ion beam column 14, a secondary charged particle detector 15, a transmitted electron detector 16, an energy dispersive X-ray fluorescence analyzer 17, an input unit 18, a display unit 19, and a control device 20.

The sample chamber 10 is formed by a pressure-resistant housing having an airtight structure capable of maintaining a desired depressurized state. The sample chamber 10 can be evacuated by an evacuation device (not illustrated) until an inside of the sample chamber 10 reaches a desired depressurized state.

The sample stage 11 holds the sample S and is disposed inside the sample chamber 10. The sample stage 11 is driven by the drive mechanism 12.

The drive mechanism 12 translates and rotates the sample stage 11 three-dimensionally. The drive mechanism 12 translates the sample stage 11 along, for example, each of X-axis, Y-axis, and Z-axis directions in a three-dimensional space. A Z axis is the up-down direction and is orthogonal to a plane (XY plane) formed by an X axis and a Y axis. The drive mechanism 12 includes, for example, a tilt mechanism that rotates the sample stage 11 around the X axis or the Y axis, and a rotation mechanism that rotates the sample stage 11 around the Z axis. Hereinafter, an angle at which the sample stage 11 is rotated by the tilt mechanism is referred to as a tilt angle.

The electron beam column 13 irradiates the sample S disposed inside the sample chamber 10 with a charged particle beam (in the embodiment, an electron beam (EB) as an example). An irradiation direction of the electron beam is, for example, parallel to the Z-axis direction. Hereinafter, for convenience of description, a direction parallel to the Z-axis direction is referred to as the up-down direction, and in the up-down direction, a vertical direction (a direction in which gravity acts) is referred to as a downward direction, and a direction opposite to the downward direction is referred to as an upward direction.

The focused ion beam column 14 irradiates the sample S disposed inside the sample chamber 10 with a focused ion beam (FIB). Accordingly, a cross section of the sample S is processed. Hereinafter, processing the sample S with the focused ion beam may be referred to as “FIB processing”.

An irradiation direction of the focused ion beam is, for example, a direction parallel to the XY plane. In the example illustrated in FIG. 1, the electron beam column 13 and the focused ion beam column 14 are arranged such that the irradiation directions thereof are orthogonal to each other on the sample S. However, the irradiation direction of the focused ion beam column 14 is not limited thereto, and may be the up-down direction or an inclined direction inclined with respect to the up-down direction. Here, in the embodiment, as an example, the FIB processing is performed such that the cross section of the sample S is parallel to each layer of the sample S.

The secondary charged particle detector 15 detects secondary electrons generated from the sample S by irradiation with an electron beam or a focused ion beam. The secondary charged particle detector 15 transmits a detection result about the secondary electrons to the control device 20.

The transmitted electron detector 16 detects transmitted electrons transmitted through the sample S and an electron beam not incident on the sample S as a result of irradiating the sample S with an electron beam. The transmitted electron detector 16 transmits a detection result to the control device 20.

The energy dispersive X-ray fluorescence analyzer 17 spectrally disperses and detects X-rays (characteristic X-rays), which are generated from the sample S as a result of irradiating the sample S with an electron beam, based on energy. The energy dispersive X-ray fluorescence analyzer 17 transmits a detection result to the control device 20.

The input unit 18 is, for example, a mouse and a keyboard that output a signal corresponding to an input operation of an operator.

The display unit 19 includes a display device such as a liquid crystal display. The display unit 19 displays various types of information on the charged particle beam apparatus 1, image data generated based on a signal output from the secondary charged particle detector 15 or the like, a screen for executing operations such as enlargement, reduction, movement, and rotation of the image data, and the like.

The control device 20 integrally controls an operation of the charged particle beam apparatus 1. The control device 20 includes an electron beam control unit 21, a focused ion beam control unit 22 (FIB control unit), a drive control unit 23, a storage unit 24, and an integrated control unit 25. These control units may be implemented by a processor.

The electron beam control unit 21 outputs an irradiation signal to the electron beam column 13 based on a signal from the integrated control unit 25, and causes the electron beam column 13 to emit an electron beam.

The focused ion beam control unit 22 outputs an irradiation signal to the focused ion beam column 14 based on a signal from the integrated control unit 25, and causes the focused ion beam column 14 to emit a focused ion beam. The focused ion beam control unit 22 can adjust the irradiation direction of the focused ion beam, which is emitted from the focused ion beam column 14, based on a signal from the integrated control unit 25.

The drive control unit 23 controls driving of the drive mechanism 12 based on a signal from the integrated control unit 25, and can translate the sample stage 11 or change the tilt angle by outputting a drive signal to the drive mechanism 12 to drive the sample stage 11.

The storage unit 24 includes a hard disk drive, a flash memory, and the like, and stores various types of information. A part or the whole of the storage unit 24 may be a non-transitory storage medium. The storage unit 24 may store a program. The control device 20 may implement the functions described in the embodiment by a processor of the control device 20 executing the program.

The storage unit 24 stores information on processing conditions for performing the FIB processing. The charged particle beam apparatus 1 scans a predetermined scanning region with a focused ion beam according to the processing conditions stored in the storage unit 24. Accordingly, the charged particle beam apparatus 1 can perform etching of the scanning region, formation of an observation image of the scanning region by the focused ion beam, and the like.

The processing conditions are information including scanning region information indicating a scanning region, information indicating an acceleration voltage of the electron beam, information indicating a beam current, information indicating a magnification, information indicating a contrast, information indicating brightness, information indicating a thickness of a layer to be cut by etching, information indicating a depth of cutting by etching, information indicating a distance from the focused ion beam column 14 to a surface of the sample S, and the like.

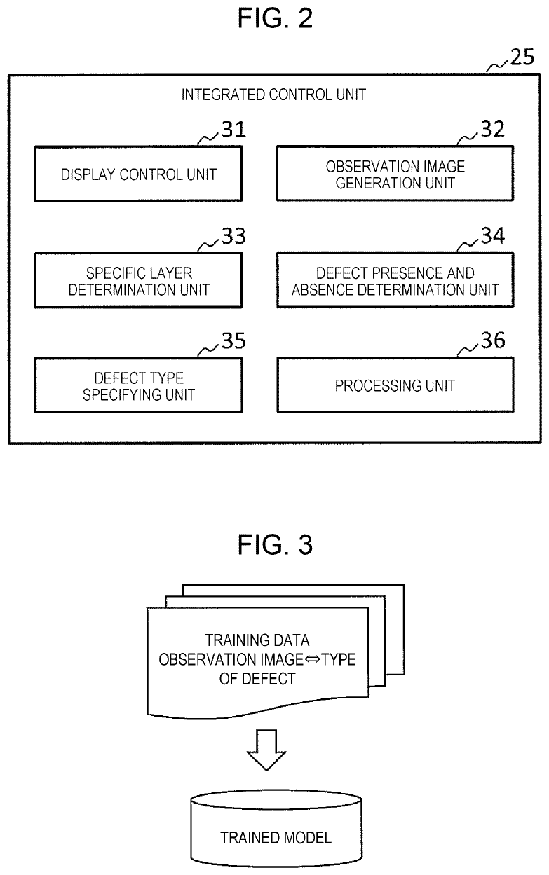

FIG. 2 is a diagram illustrating an example of a schematic configuration of the integrated control unit 25 according to the embodiment. The integrated control unit 25 includes a display control unit 31, an observation image generation unit 32, a specific layer determination unit 33, a defect presence and absence determination unit 34, a defect type specifying unit 35, and a processing unit 36.

The display control unit 31 causes the display unit 19 to display the transmission image or the SEM image described above.

The observation image generation unit 32 generates a transmission image based on a signal for performing scanning with the electron beam from the electron beam control unit 21 and a signal of transmitted electrons detected by the transmitted electron detector 16. The observation image generation unit 32 generates SEM image data based on the signal for performing scanning with the electron beam from the electron beam control unit 21 and a signal of the secondary electrons detected by the secondary charged particle detector 15. The observation image of the embodiment is an SEM image, and may be a transmission image.

The specific layer determination unit 33 determines, based on the observation image generated by the observation image generation unit 32, whether the specific layer among the plurality of layers of the sample S is exposed. For example, the specific layer determination unit 33 applies known image processing to the observation image generated by the observation image generation unit 32 to acquire a pattern of a cross section appearing in the observation image. When the acquired pattern coincides with a pattern of the specific layer registered in advance in the storage unit 24 or the like, the specific layer determination unit 33 determines that the specific layer is exposed. However, the invention is not limited thereto, and the specific layer determination unit 33 may use another known technique to determine, based on the observation image, whether the specific layer is exposed.

The defect presence and absence determination unit 34 determines whether a defect is in the specific layer based on the observation image generated by the observation image generation unit 32 in which the specific layer is determined to be exposed by the specific layer determination unit 33. For example, the defect presence and absence determination unit 34 determines the presence or absence of a defect based on the observation image generated by the observation image generation unit 32 and reference data registered in advance in the storage unit 24 or the like. Further, when it is determined that there is a defect, a position of the defect in the observation image may be specified.

The reference data is data indicating a structure and/or appearance of the defect-free sample S, and a format thereof may be any format. For example, CAD data of the specific layer may be used, other design data may be used, an observation image or other images may be used, or data in other formats may be used.

The processing of determining the presence or absence of a defect may be based on, for example, a difference between the reference data and the observation image generated by the observation image generation unit 32. Here, the “difference” is, for example, a difference in luminance value or color value of each pixel in the image. Comparison processing other than the difference may be used.

When the defect presence and absence determination unit 34 determines that there is a defect in the observation image generated by the observation image generation unit 32, the defect type specifying unit 35 specifies the type or shape of the defect in the specific layer based on the observation image. For example, the defect type specifying unit 35 specifies the type or shape of the defect based on the observation image by using a trained model. In this way, the defect type specifying unit 35 may function as a defect shape specifying unit.

FIG. 3 is a diagram illustrating an example of a method of generating a trained model according to the embodiment. The trained model is, for example, a model trained to output the type of defect according to the input of the observation image generated by the observation image generation unit 32. The trained model is generated in advance, for example, by executing machine learning using training data in which an observation image of a specific layer having a defect is associated with a type of the defect. By using such training data, the type of the defect can be appropriately specified. Content and/or format of available training data is not limited thereto. The generated trained model can be registered in the storage unit 24 in advance.

The type of the defect can be appropriately defined by those skilled in the art or a user of the charged particle beam apparatus 1, and may include, for example, a depletion defect (a defect that a depletion portion is present in the sample S), and a foreign matter defect (a defect that a foreign matter is contained in the sample S). Those skilled in the art can appropriately design, based on a known technique or the like, the processing for specifying the shape of the defect based on the observation image.

The charged particle beam apparatus 1 or the processing unit 36 executes predetermined different processing based on the presence or absence of a defect determined by the defect presence and absence determination unit 34 and/or the type or shape of the defect determined by the defect type specifying unit 35. That is, the charged particle beam apparatus 1 or the processing unit 36 may execute different processing based on the presence or absence of a defect, or may execute different processing based on the type or shape of the defect. Although details will be described later, the different processing includes, for example, detailed observation of a defect portion, elemental analysis based on energy dispersive X-ray fluorescence analysis (EDX), thinning processing for TEM observation, continuous cross-section processing and observation for constructing a three-dimensional model, and similar processing for a next sample. The observation image may be acquired again by correcting a beam irradiation position with respect to a specified position of the defect such that the defect is a center of the observation image (or such that the defect is closer to the center of the observation image).

Hereinafter, a processing method will be described in which the charged particle beam apparatus 1 exposes a specific layer, determines whether a defect is in the exposed specific layer, specifies a position of the defect when there is a defect, specifies a type or a shape of the defect, and executes predetermined processing according to the type or the shape of the defect.

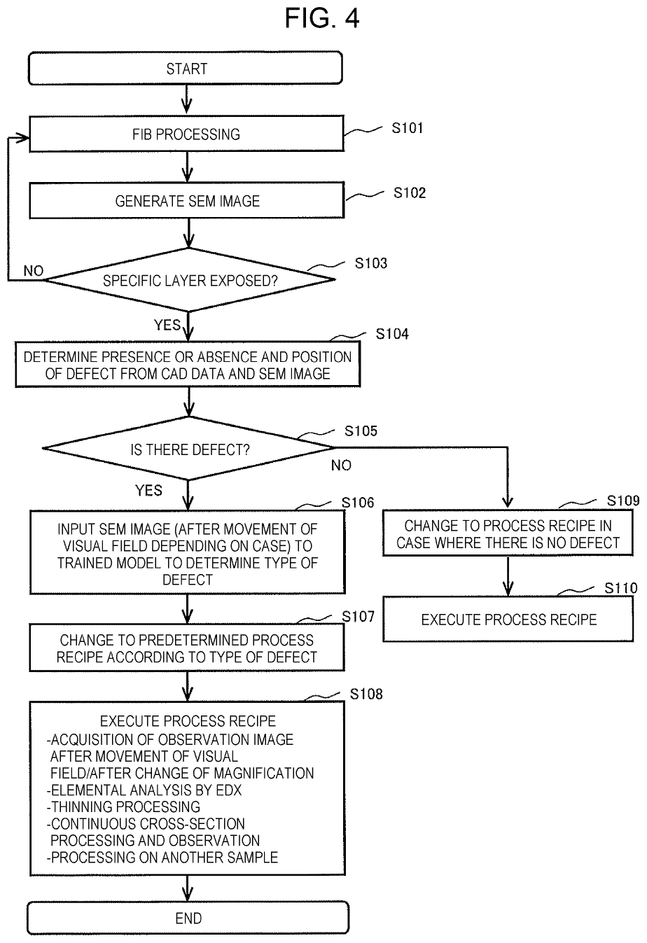

FIG. 4 is a flowchart of the processing method executed by the charged particle beam apparatus 1 according to the embodiment.

### Processing Method

The charged particle beam apparatus 1 reads processing conditions stored in the storage unit 24 and starts FIB processing according to the processing conditions. First, the charged particle beam apparatus 1 irradiates the sample S with a focused ion beam to process a cross section of the sample S (step S101: processing step). The processing is performed by, for example, slicing by a specified amount. In this way, a new cross section is formed, and a new layer is exposed. In the following description, the “cross section” can be referred to as a “layer”.

The charged particle beam apparatus 1 stops the FIB processing after the new cross section is formed, irradiates the cross section of the processed sample S with an electron beam, and generates an observation image of the cross section (hereinafter, SEM image in the embodiment) (step S102: image generation step). That is, the observation image generation unit 32 executes the image generation step after the processing step.

Next, the charged particle beam apparatus 1 determines whether a specific layer is exposed based on the SEM image generated in the image generation step (step S103: specific layer determination step).

For example, the specific layer determination unit 33 compares the SEM image obtained in the image generation step and a cross-sectional image of the specific layer stored in the storage unit 24 in advance (hereinafter referred to as a “target cross-sectional image”), and determines whether the SEM image and the target cross-sectional image coincides with each other.

If the SEM image and the target cross-sectional image do not coincide with each other, the specific layer determination unit 33 determines that the specific layer is not exposed. In this case, the process in FIG. 4 returns to the processing of step S101 so that the slice processing is executed again.

On the other hand, if the SEM image obtained in the image generation step coincides with the target cross-sectional image stored in the storage unit 24 in advance, the specific layer determination unit 33 determines that the specific layer is exposed. If the specific layer determination unit 33 determines that the specific layer is exposed, loop processing including steps S101 to S103 is ended.

In this way, the charged particle beam apparatus 1 exposes the specific layer. Here, as described above, the processing of exposing the specific layer includes the loop processing including steps S101 to S103, and this loop processing is repeatedly executed until it is determined that the specific layer is exposed. In other words, the charged particle beam apparatus 1 sets the processing step, the image generation step, and the specific layer determination step as one set, and repeatedly executes the set until the exposure of the specific layer is detected in the specific layer determination step.

After it is determined that the specific layer is exposed, the charged particle beam apparatus 1 determines whether there is a defect based on the SEM image, in which it is determined that the specific layer is exposed in the specific layer determination step, and predetermined reference data (for example, CAD data) (step S104: defect presence and absence determination step). Further, if it is determined that there is a defect, a position of the defect in the observation image may be specified.

In step S104, a specific method of determining whether there is a defect can be appropriately designed by those skilled in the art based on a known technique or the like, and for example, if a portion having abnormal luminance is detected in the observation image, it can be determined that there is a defect.

The process in FIG. 4 branches according to a determination result of step S104 (step S105). If it is determined that there is a defect, the process proceeds to step S106, and if it is determined that there is no defect, the process proceeds to step S109.

The charged particle beam apparatus 1 specifies a type or shape of the defect by using a trained model as described above based on the SEM image, by which it is determined in the defect presence and absence determination step that there is a defect (step S106: defect type specifying step).

In step S106, not only the SEM image itself, by which it is determined in the defect presence and absence determination step that there is a defect, but also another SEM image of the sample S may be used. For example, a new SEM image may be acquired by setting the irradiation position of the electron beam such that the defect is the center of the SEM image or is closer to the center, and the type or shape of the defect may be specified based on the newly acquired SEM image. In this way, specifying accuracy is improved.

The charged particle beam apparatus 1 changes a process recipe according to the specified type or shape of the defect (step S107). That is, a different process recipe is set according to the type or shape of the defect. Thereafter, the charged particle beam apparatus 1 executes the set process recipe (step S108).

In step S107, association between the type or shape of the defect and the set process recipe is stored in advance in, for example, the storage unit 24. The user of the charged particle beam apparatus 1 can input information indicating the association to the charged particle beam apparatus 1 in advance and store the information in the storage unit 24.

Specific content of the process recipe can be appropriately designed by those skilled in the art or a user of the charged particle beam apparatus 1, and includes, for example, a process recipe corresponding to the following processing.
Acquisition of observation image after movement of visual field. For example, an observation image is acquired by setting the irradiation position of the electron beam such that the defect is the center of the observation image or is closer to the center.
Acquisition of observation image after change of magnification. For example, an observation image is acquired with a larger magnification.
Acquisition of observation image after movement of field of view and after change of magnification.
   Elemental analysis of sample S based on EDX.
Thinning of sample S for TEM observation or other applications.
Continuous cross-section processing and observation for construction of three-dimensional model of sample S. This processing may be, for example, processing called Cut & see. The continuous cross-section processing and observation can be executed by, for example, repeatedly executing the same processing as steps S101 to S103, sequentially acquiring and storing observation images of different positions, and generating a three-dimensional shape based on the obtained observation images.
Similar processing on another sample. For example, after the process in FIG. 4 is ended and the sample S is manually or automatically replaced with another sample, the process in FIG. 4 is executed on the other sample. As described above, this processing includes exposing the specific layer with respect to the other sample.

The different processing includes determining not to execute the processing. That is, it may be determined not to execute the process recipe. In this case, the process in FIG. 4 may be ended without executing special processing on the sample S.

As described above, by defining specific process recipes having various types of content, various types of processing on the sample S can be automatically executed.

If it is determined in step S105 that there is no defect, the process recipe is changed to a process recipe corresponding to predetermined processing for a case where there is no defect (step S109). That is, a process recipe for the case where there is no defect is set in the charged particle beam apparatus 1. Thereafter, the charged particle beam apparatus 1 executes the set process recipe (step S110).

As described above, by separately preparing the process recipe for step S108 and the process recipe for step S110, it is possible to use an appropriate process recipe according to the presence or absence of a defect. As a specific example, different processing can be executed when a depletion defect is present, when a foreign matter defect is present, and when no defect is present.

The content of the process recipe in step S110 can be appropriately designed by those skilled in the art or a user of the charged particle beam apparatus 1, and may include, for example, a process recipe corresponding to the same processing as step S108. In particular, since a thin piece of a defect-free sample is useful in TEM observation or the like, it is beneficial that the process recipe in step S110 includes thinning processing of the sample S for TEM observation or other applications.

As described above, according to the charged particle beam apparatus 1 of the embodiment, by automatically setting process recipes having different content according to the state of the cross section of the sample (for example, the presence or absence of a defect and the type or shape of the defect), it is possible to execute desired processing while eliminating the need for specialized determination and complicated work performed by a human.

In Embodiment 1 described above, the steps S101 to S103 are repeatedly executed until it is determined that the specific layer is exposed, and as a modification, when a defect is found before reaching the specific layer, the type or shape of the defect may be specified. For example, the steps S104 and S105 may be executed between steps S102 and S103, and the determination regarding the defect may be performed for each layer in the loop. Then, different processing may be executed according to the specified type or shape of the defect. In this way, it is possible to perform appropriate processing for a defect in a layer other than the specific layer.

### REFERENCE SIGNS LIST

1: charged particle beam apparatus
10: sample chamber
11: sample stage
12: drive mechanism
13: electron beam column (charged particle beam column)
14: focused ion beam column
15: secondary charged particle detector
16: transmitted electron detector
17: energy dispersive X-ray fluorescence analyzer
18: input unit
19: display unit
20: control device
21: electron beam control unit
22: focused ion beam control unit
23: drive control unit
24: storage unit
25: integrated control unit
31: display control unit
32: observation image generation unit
33: specific layer determination unit
34: defect presence and absence determination unit
35: defect type specifying unit
36: processing unit
S: sample

1.-8. (canceled)

9. A processing method for a sample in which a plurality of layers are stacked, the processing method comprising:
presetting processing to be performed on a specific layer according to a type or a shape of a defect appearing in the specific layer;
irradiating the sample with a focused ion beam by a charged particle beam apparatus to expose the layer;
irradiating the exposed layer with a charged particle beam to generate an observation image of the layer;
determining whether the specific layer is exposed based on the observation image of the layer;
when it is determined that there is a defect in the exposed specific layer, specifying a type or a shape of the defect based on an observation image of the sample by using a trained model;
executing the preset processing in the charged particle beam apparatus according to the specified type or shape of the defect; and
when it is determined that there is no defect in the layer, executing a process recipe for a case where there is no defect, which is prepared separately from the processing for a case where there is the defect, wherein
the predetermined processing for the case where there is the defect includes at least one of
elemental analysis based on energy dispersive X-ray fluorescence analysis,
thinning processing,
continuous cross-section processing and observation for constructing a three-dimensional model, or
execution of no process recipe, and
execution of different processing is enabled for a case where there is a depletion defect, a case where there is a foreign matter defect, and a case where there is no defect.

10. The processing method according to claim 9, further comprising:
determining whether there is a defect based on reference data regarding the specific layer and the observation image after it is determined that the specific layer is exposed; and
according to whether there is the defect, executing the processing for the case where there is the defect or the process recipe for the case where there is no defect.

11. The processing method according to claim 9, wherein
the predetermined processing for the case where there is the defect includes at least one of
acquisition of the observation image after movement of a visual field and/or after a change of a magnification, or
execution of the processing method according to claim 9 on another sample.

12. The processing method according to claim 9, further comprising:
specifying, when it is determined that there is a defect, a position of the defect, wherein
the specifying the type or the shape of the defect is performed based on an observation image acquired by setting an irradiation position of the charged particle beam such that the defect is closer to a center of the observation image.

13. The processing method according to claim 9, further comprising:
generating the trained model by executing machine learning using training data in which an observation image of the layer having the defect is associated with a type of the defect.

14. A charged particle beam apparatus for processing a sample in which a plurality of layers are stacked, the charged particle beam apparatus comprising:
a focused ion beam lens barrel;
a charged particle beam lens barrel; and
a processor, wherein
the processor presets processing to be performed on a specific layer according to a type or a shape of a defect appearing in the specific layer,
the focused ion beam lens barrel irradiates the sample with a focused ion beam to expose the layer,
the charged particle beam lens barrel irradiates the exposed layer with a charged particle beam,
the processor
generates an observation image of the layer,
determines whether the specific layer is exposed based on the observation image of the layer, and
when it is determined that there is a defect in the exposed specific layer, specifies a type or a shape of the defect based on an observation image of the sample by using a trained model,
the charged particle beam apparatus executes the preset processing according to the specified type or shape of the defect,
when it is determined that there is no defect in the layer, the processor executes a process recipe for a case where there is no defect, which is prepared separately from the processing for a case where there is the defect,
the predetermined processing for the case where there is the defect includes at least one of
elemental analysis based on energy dispersive X-ray fluorescence analysis,
thinning processing,
continuous cross-section processing and observation for constructing a three-dimensional model, or
execution of no process recipe, and
execution of different processing is enabled for a case where there is a depletion defect, a case where there is a foreign matter defect, and a case where there is no defect.

15. The charged particle beam apparatus according to claim 14, wherein
the processor further determines whether there is a defect based on reference data regarding the specific layer and the observation image after it is determined that the specific layer is exposed, and
according to whether there is the defect, the charged particle beam apparatus executes the processing for the case where there is the defect or the process recipe for the case where there is no defect.
